(19) United States
(12) Patent Application Publication
(10) Pub. No.: US 2026/0066883 A1
(43) Pub. Date: Mar. 5, 2026

(54) Ablation Systems, Devices, and Methods

(71) Applicant: EHT Ventures LLC, Seattle, WA (US)

(72) Inventors: Alex Henson, Seattle, WA (US); Kevin Muggli, Mountlake Terrace, WA (US); Timothy Ziemba, Bainbridge Island, WA (US); Kenneth Miller, Seattle, WA (US)

(21) Appl. No.: 18/736,526

(22) Filed: Aug. 28, 2024

Related U.S. Application Data
(63) Continuation-in-part of application No. 18/512,002, filed on Nov. 16, 2023, now Pat. No. 12,348,228.
Application No. 18/512,002 is a continuation of application No. 17/853,891, filed on Jun. 29, 2022, now Pat. No. 11,824,542.

(51) Int. Cl. H03K 3/57; H02M 3/07

(52) U.S. Cl. CPC H03K 3/57; H02M 3/07

(57) ABSTRACT

Bipolar high voltage bipolar pulsing ablation systems, devices, and methods are disclosed that include power supplies that can produce high voltage bipolar pulses with a positive high voltage pulse greater than about 200 V followed by a negative high voltage pulse less than about −200 V with a positive to negative dwell period between the positive high voltage pulse and the negative high voltage pulse. A high voltage bipolar pulsing power supply, for example, can reproduce high voltage pulses with a pulse repetition frequency greater than about 10 kHz.

### BACKGROUND

Tissue ablation can be used to address a variety of medical issues. For example, for cardiac applications specialized multielectrode catheters have been used to deliver electroporation to the ostium of the pulmonary veins within the left atrium. Tissue ablation, however, needs to be controlled to not destroy surrounding healthy tissue. Accordingly, there is a need for ablation systems, devices, and methods that can provide be controlled to limit ablation to desired tissues and/or locations.

### SUMMARY

Bipolar high voltage pulsing ablation systems, devices, and methods are disclosed that include a power supply that can produce high voltage bipolar pulses with a positive high voltage pulse greater than about 200 V followed by a negative high voltage pulse less than about −200 V with a positive to negative dwell period between the positive high voltage pulse and the negative high voltage pulse. A high voltage bipolar pulsing power supply used in ablation devices, methods, and systems described herein can, for example, reproduce high voltage pulses with a high pulse repetition frequency greater than about 10 kHz. Ablation systems, devices, and methods including power systems provided in this document can allow for improved of ablation by electroporation.

A bipolar high voltage bipolar pulsing power supply, for example, is disclosed that can produce high voltage bipolar pulses with a positive high voltage pulse greater than about 2 kV followed by a negative high voltage pulse less than about −2 kV with a positive to negative dwell period between the positive high voltage pulse and the negative high voltage pulse. A high voltage bipolar pulsing power supply, for example, can reproduce high voltage pulses with a high pulse repetition frequency greater than about 10 kHz.

A high voltage bipolar pulsing power supply, for example, is disclosed that includes a DC source; an energy storage capacitor coupled with the DC source; a first high voltage switch electrically coupled with the DC source and the energy storage capacitor; a first diode arranged across the first high voltage switch; a second high voltage switch electrically coupled with the DC source and the energy storage capacitor; a second diode arranged across the second high voltage switch; a third high voltage switch arranged in series between the first high voltage switch and ground; a third diode arranged across the third high voltage switch; a fourth high voltage switch arranged in series between the second high voltage switch and ground; a fourth diode arranged across the fourth high voltage switch; and an output having a first lead electrically coupled between first high voltage switch and the third high voltage switch and the second lead electrically coupled between second high voltage switch and the fourth high voltage switch.

In some examples, the first high voltage switch, the second high voltage switch, the third high voltage switch, and/or the fourth high voltage switch each have a capacitance less than about 10 nF.

In some examples, the first high voltage switch comprises a first plurality of solid-state switches arranged in parallel, the second high voltage switch comprises a second plurality of solid-state switches arranged in parallel, the third high voltage switch comprises a third plurality of solid-state switches arranged in parallel, and/or the fourth high voltage switch comprise a fourth plurality of solid state switches arranged in parallel.

In some examples, the first high voltage switch, the second high voltage switch, the third high voltage switch, and/or the fourth high voltage switch each comprise a switch selected from the group consisting of an IGBT, a MOSFET, a SiC MOSFET, a SiC junction transistor, a FET, a SiC switch, a GaN switch, and a photoconductive switch.

In some examples, the circuit comprising both the DC source and the energy storage capacitor has an inductance less than about 10 nH.

In some examples, the circuit comprising both the first high voltage bipolar pulsing power supply and the second high voltage switch has an inductance less than about 10 nH.

In some examples, the first lead of the output is coupled with a first lead of an electrode and the second lead of the output is coupled with a second lead of the electrode.

The high voltage bipolar pulsing power supply, for example, can also include a first tail sweeper switch and a first tail sweeper resistor arranged in series across the first high voltage switch; a second tail sweeper switch and a second tail sweeper resistor arranged in series across the first high voltage switch; a third tail sweeper switch and a third tail sweeper resistor arranged in series across the first high voltage switch; and a fourth tail sweeper switch and a fourth tail sweeper resistor arranged in series across the first high voltage switch.

A high voltage, multilevel, bipolar pulsing power supply, for example, is disclosed that includes: a first DC source; a first energy storage capacitor coupled with the first DC source; a first diode having an anode and a cathode, the anode electrically coupled with the first DC source and the first energy storage capacitor; a first high voltage switch electrically coupled with the cathode of the first diode; a first diode arranged across the first high voltage switch; a second high voltage switch electrically coupled with the cathode of the first diode; a second diode arranged across the second high voltage switch; a third high voltage switch arranged in series between the first high voltage switch and ground; a third diode arranged across the third high voltage switch; a fourth high voltage switch arranged in series between the second high voltage switch and ground; a fourth diode arranged across the fourth high voltage switch; a second DC source; a second energy storage capacitor coupled with the second DC source; a fifth high voltage switch electrically coupled with the second DC source and the second energy storage capacitor; a fifth diode arranged across the fifth high voltage switch; a sixth high voltage switch electrically coupled with the cathode of the second DC source and the second energy storage capacitor; a sixth diode arranged across the sixth high voltage switch; and an output having a first lead electrically coupled between first high voltage switch and the third high voltage switch and the second lead electrically coupled between second high voltage switch and the fourth high voltage switch.

In some examples, the second DC source produces a voltage greater than the first DC source.

In some examples, the first high voltage switch, the fourth high voltage switch, and the fifth high voltage switch are closed to produce a voltage at the output equal to a voltage of the second DC source; the second high voltage switch, the third high voltage switch, and the sixth high voltage switch are closed to produce a voltage at the output equal to a negative voltage of the second DC source; the first high voltage switch and the fourth high voltage switch are closed to produce a voltage at the output equal to a voltage of the first DC source; and the second high voltage switch and the third high voltage switch are closed to produce a voltage at the output equal to a negative voltage of the first DC source.

In some examples, the first high voltage switch, the second high voltage switch, the third high voltage switch, the fourth high voltage switch, the fifth high voltage switch, and the sixth high voltage switch each have a capacitance less than about 500 pF.

The high voltage bipolar pulsing power supply, for example, may also include a first tail sweeper switch and a first tail sweeper resistor arranged in series across the first high voltage switch; a second tail sweeper switch and a second tail sweeper resistor arranged in series across the first high voltage switch; a third tail sweeper switch and a third tail sweeper resistor arranged in series across the first high voltage switch; a fourth tail sweeper switch and a fourth tail sweeper resistor arranged in series across the first high voltage switch; a fifth tail sweeper switch and a fifth tail sweeper resistor arranged in series across the fifth high voltage switch; and a sixth tail sweeper switch and a sixth tail sweeper resistor arranged in series across the sixth high voltage switch.

A high voltage, multilevel, bipolar pulsing power supply, for example, is disclosed that includes: a DC source; an energy storage capacitor coupled with the DC source; a diode having an anode and a cathode, the anode electrically coupled with the DC source and the energy storage capacitor; a first high voltage switch electrically coupled with the cathode of the diode; a first diode arranged across the first high voltage switch; a first tail sweeper switch and a first tail sweeper resistor arranged in series across the first high voltage switch; a second high voltage switch electrically coupled with the cathode of the diode; a second diode arranged across the second high voltage switch; a second tail sweeper switch and a second tail sweeper resistor arranged in series across the first high voltage switch; a third high voltage switch arranged in series between the first high voltage switch and ground; a third diode arranged across the third high voltage switch; a third tail sweeper switch and a third tail sweeper resistor arranged in series across the first high voltage switch; a fourth high voltage switch arranged in series between the second high voltage switch and ground; a fourth diode arranged across the fourth high voltage switch; a fourth tail sweeper switch and a fourth tail sweeper resistor arranged in series across the first high voltage switch; and an output having a first lead electrically coupled between first high voltage switch and the third high voltage switch and the second lead electrically coupled between second high voltage switch and the fourth high voltage switch.

In some examples, the first tail sweeper switch is closed prior to the first high voltage switch being closed; the second tail sweeper switch is closed prior to the second high voltage switch being closed; the third tail sweeper switch is closed prior to the third high voltage switch being closed; and the fourth tail sweeper switch is closed prior to the fourth high voltage switch being closed.

In some examples, the first high voltage switch, the second high voltage switch, the third high voltage switch, and the fourth high voltage switch each comprise a switch selected from the group consisting of an IGBT, a MOSFET, a SiC MOSFET, a SiC junction transistor, a FET, a SiC switch, a GaN switch, and a photoconductive switch.

In some examples, the first tail sweeper switch, the second tail sweeper switch, the third tail sweeper switch, and the fourth tail sweeper switch each comprise a switch selected from the group consisting of an IGBT, a MOSFET, a SiC MOSFET, a SiC junction transistor, a FET, a SiC switch, a GaN switch, and a photoconductive switch.

In some examples, the circuit between the diode and both the DC source and the energy storage capacitor has an inductance less than about 10 nH.

In some examples, the circuit between the diode and the first high voltage bipolar pulsing power supply and the second high voltage switch has an inductance less than about 10 nH.

In some examples, the first lead of the output is coupled with a first lead of an electrode and the second lead of the output is coupled with a second lead of the electrode

Bipolar high voltage ablation systems, devices, and methods can, for example, include a tissue ablation catheter that includes more or more electrodes for electroporation. In some examples, a catheter can include an insulator between inner and outer electrodes. In some examples, arrangements of electrodes for electroporation on a catheter can generate novel electric field shapes that may improve ablation targeting and/or consistency.

Bipolar high voltage ablation systems, devices, and methods can include a controller to control the pulses delivered to one or more electrodes for electroporation. In some examples, a controller can be used to control the pulses delivered to one or more electrodes for electroporation on a catheter to generate novel electric field shapes that may improve ablation targeting and/or consistency.

Bipolar high voltage ablation systems, devices, and methods in some examples can include a catheter with a tubular element having a longitudinal axis, a distal end, a lumen, an inner surface surrounding the lumen, and an outer surface. There may be an electrical insulator between the inner surface and the outer surface. The catheter may have one or more inner electrodes coupled to the inner surface, and one or more outer electrodes coupled to the outer surface. The inner electrodes and the outer electrodes may each be offset from the distal end of the catheter. The electrical insulator may separate the inner electrodes from the outer electrodes. The distal end of the catheter may be placed near a tissue to ablated. The controller may set the voltages of the inner and outer electrodes to generate an electric field outside the tubular element that induces ablation of the tissue by electroporation.

In one or more examples, the shortest path of electrical current flowing from an inner electrode to an outer electrode may be longer than the distance between the inner and outer electrode.

In one or more examples, the electrical insulator may be a dielectric, such as aluminum nitride ceramic for example. In one or more examples the conductivity of the electrical insulator may be less than 0.1 micro-Siemens per centimeter.

In one or more examples, the distance between the distal end of the catheter tubular element and each of the inner electrodes may be greater than or equal to 0.01 millimeters and less than or equal to 1 meter. In one or more examples the distance between the distal end of the catheter tubular element and each of the outer electrodes may be greater than or equal to 0.01 millimeters and less than or equal to 1 meter.

In one or more examples, the controller may set a potential difference between at least one inner electrode and at least one outer electrode of greater than 5000 volts.

In one or more examples, the controller may modify the voltages of the inner and outer electrodes within a pulse time that is less than two times the membrane recovery time of the tissue to be ablated.

In one or more examples, the controller may modify the voltages at the inner and outer electrodes within a period that is less than or equal to 10 milliseconds.

In one or more examples, the controller may modify voltages at to the inner and outer electrodes to change the direction of the electric field outside the tubular element over time. For example, the controller may set electrode voltages at one time to generate a first average electric field vector in a region of the tissue to be ablated and may set electrode voltages at another time to generate a second average electric field vector in a region of the tissue to be ablated, where the angular difference between the first and second average electric field vector is at least 1 degree.

The various examples and examples described in the summary and this document are provided not to limit or define the disclosure or the scope of the claims.

### BRIEF DESCRIPTION OF THE FIGURES

FIG. 1A shows an example ablation system including a pulsed-field ablation device having an electrode array portion.

FIG. 1B is an example illustration of a high voltage bipolar pulsing power supply driving a load.

FIG. 2A shows an output waveform at the load from the bipolar pulsing power supply.

FIG. 2B shows the open and close switch logic of the switches in the bipolar pulsing power supply shown in FIG. 1 to produce the waveforms shown in FIG. 2A.

FIG. 3A shows an output waveform at the load from the bipolar pulsing power supply.

FIG. 3B shows the open and close switch logic of the switches in the bipolar pulsing power supply shown in FIG. 1 to produce the waveforms shown in FIG. 3A.

FIG. 4A shows an output waveform at the load from the bipolar pulsing power supply.

FIG. 4B shows the open and close switch logic of the switches in the bipolar pulsing power supply shown in FIG. 1 to produce the waveforms shown in FIG. 4A.

FIG. 5 shows output burst waveforms from a bipolar pulsing power supply.

FIG. 6 is an example illustration of a high voltage, bipolar, multilevel, bipolar pulsing power supply driving a load.

FIG. 7A shows an output waveform at the load from the bipolar, multilevel, pulsing power supply.

FIG. 7B shows the open and close switch logic of the switches in the bipolar, multilevel, pulsing power supply shown in FIG. 6 to produce the waveforms shown in FIG. 7A.

FIG. 8A shows an output waveform at the load from the bipolar, multilevel, pulsing power supply.

FIG. 8B shows the open and close switch logic of the switches in the bipolar, multilevel, pulsing power supply shown in FIG. 6 to produce the waveforms shown in FIG. 8A.

FIG. 9A shows an output waveform at the load from the bipolar, multilevel, pulsing power supply.

FIG. 9B shows the open and close switch logic of the switches in the bipolar, multilevel, pulsing power supply shown in FIG. 6 to produce the waveforms shown in FIG. 8A.

FIG. 10 is an example illustration of a high voltage, bipolar, multilevel, bipolar pulsing power supply driving a load.

FIG. 11 is an example illustration of a high voltage bipolar pulsing power supply driving a load.

FIG. 12A shows an output waveform at the load from the bipolar, pulsing power supply shown in FIG. 11.

FIG. 12B shows the open and close switch logic of the switches in the bipolar, pulsing power supply shown in FIG. 11 to produce the waveforms shown in FIG. 12A.

FIG. 13 is a block diagram of a computational system that can be used to with or to perform some examples described in this document.

FIG. 14A shows an alternative ablation catheter that can be used as part of system of FIG. 1A. FIG. 14B shows a cross-section view of catheter of FIG. 14A.

FIG. 15A show an alternative ablation catheter that can be used as part of system of FIG. 1A, which includes an ablation catheter with an outer electrode and an inner electrode. FIG. 15B shows a cross-section view of catheter of FIG. 15A. FIG. 15C shows illustrative electric field vectors in the region around the distal end of the catheter of FIG. 15A; the electric field bends around the insulator at the distal end between the inner and outer electrode.

### DETAILED DESCRIPTION

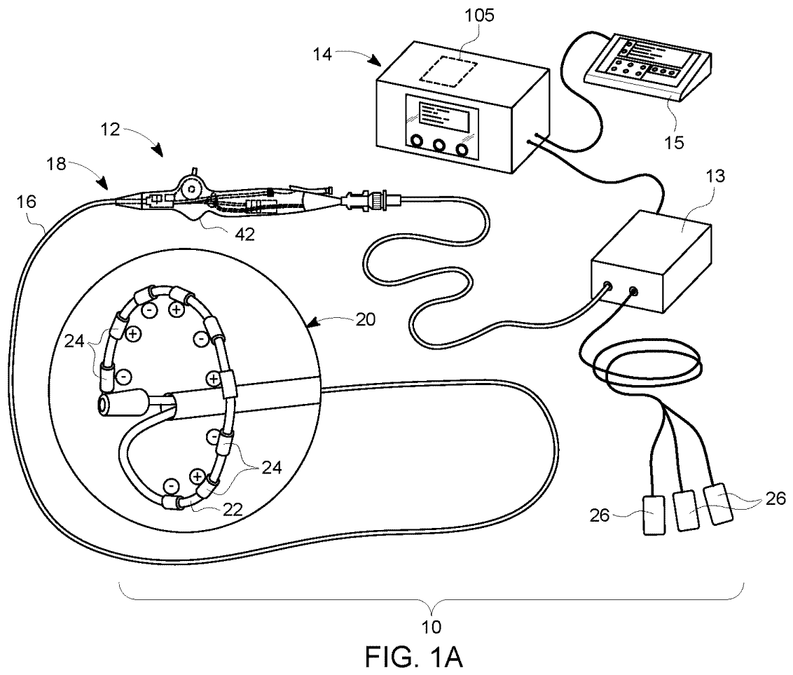

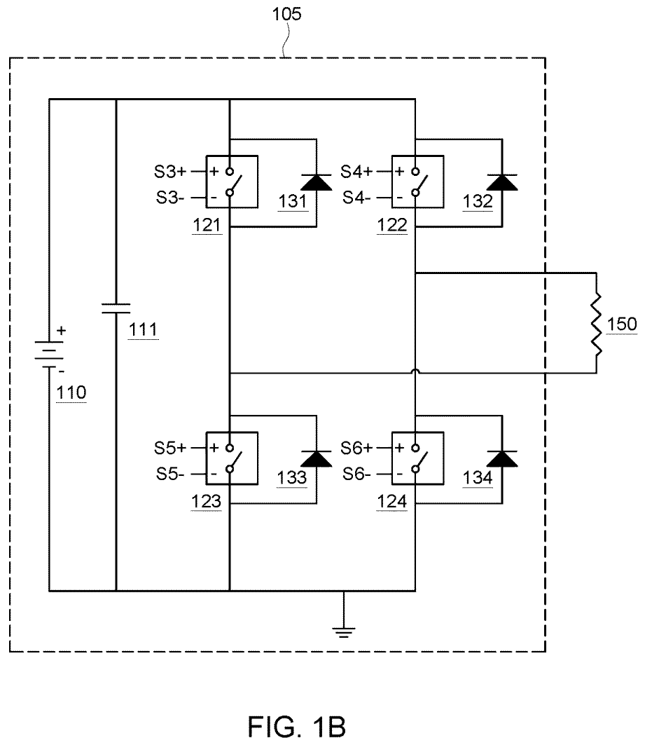

The present application provides methods and systems for treating undesirable physiological or anatomical tissue regions, such as, for example, those contributing to aberrant electrical pathways in the heart. Referring now to the drawing figures in which like reference designations refer to like elements, an example of a medical system 10 is shown in FIG. 1A. The system 10 generally includes a medical device 12 that may be coupled directly to an energy supply, for example, a pulse field ablation generator 14 including a high voltage bipolar pulsing power supply 105 and an energy control, delivering and monitoring system or indirectly through a catheter electrode distribution system 13. A remote controller 15 may further be included in communication with the generator for operating and controlling the various functions of the ablation generator 14. The medical device 12 may generally include one or more treatment regions for energetic, therapeutic and/or investigatory interaction between the medical device 12 and a treatment site. The treatment region(s) may deliver, for example, pulsed electroporation energy to a tissue area in proximity to the treatment region(s).

The medical device 12 may include an elongate body 16 passable through a patient's vasculature and/or positionable proximate to a tissue region for treatment, such as a catheter, sheath, or intravascular introducer. The elongate body 16 may define a proximal portion 18 and a distal portion 20 and may further include one or more lumens disposed within the elongate body 16 thereby providing mechanical, electrical, and/or fluid communication between the proximal portion of the elongate body 16 and the distal portion of the elongate body 16. The distal portion 20 may generally define the one or more treatment region(s) of the medical device 12 that are operable to monitor, diagnose, and/or treat a portion of a patient. The treatment region(s) may have a variety of configurations to facilitate such operation. The distal portion 20 includes electrodes that form the bipolar configuration for energy delivery. In an alternate configuration, a plurality of the electrodes 24 may serve as one pole while a second device containing one or more electrodes (not pictured) would be placed to serve as the opposing pole of the bipolar configuration. For example, as shown in FIG. 1A, the distal portion 20 may include an electrode carrier arm 22 that is transitionable between a linear configuration and an expanded configuration in which the carrier arm 22 has an arcuate or substantially circular configuration. The carrier arm 22 may include the plurality of electrodes 24 (for example, nine electrodes 24, as shown in FIG. 1A) that are configured to deliver pulsed-field energy. Alternatively, the medical device 12 may have a linear configuration with the plurality of electrodes 24. For example, the distal portion 20 may include six electrodes 24 linearly disposed along a common longitudinal axis.

The ablation generator 14 may include processing circuitry, such as a processor 17 communication with one or more controllers and/or memories containing software modules containing instructions or algorithms to provide for the automated operation and performance of the features, sequences, calculations, or procedures described herein. The system 10 may further include three or more surface ECG electrodes 26 on the patient in communication with the ablation generator 14 through the catheter electrode distribution box 13 to monitor the patient's cardiac activity for use in determining pulse train delivery timing at the desired portion of the cardiac cycle, for example, during the ventricular refractory period. In addition to monitoring, recording or otherwise conveying measurements or conditions within the medical device 12 or the ambient environment at the distal portion of the medical device 12, additional measurements may be made through connections to the multi-electrode catheter including for example temperature, electrode-tissue interface impedance, delivered charge, current, power, voltage, work, or the like in the ablation generator 14 and/or the medical device 12. The surface ECG electrodes 26 may be in communication with the ablation generator 14 for initiating or triggering one or more alerts or therapeutic deliveries during operation of the medical device 12. Additional neutral electrode patient ground patches (not pictured) may be employed to evaluate the desired bipolar electrical path impedance, as well as monitor and alert the operator upon detection of inappropriate and/or unsafe conditions. which include, for example, improper (either excessive or inadequate) delivery of charge, current, power, voltage and work performed by the plurality of electrodes 24; improper and/or excessive temperatures of the plurality of electrodes 24, improper electrode-tissue interface impedances; improper and/or inadvertent electrical connection to the patient prior to delivery of high voltage energy by delivering one or more low voltage test pulses to evaluate the integrity of the tissue electrical path.

The ablation generator 14 may include an electrical current or pulse generator having a plurality of output channels, with each channel coupled to an individual electrode of the plurality of electrodes 24 or multiple electrodes of the plurality of electrodes 24 of the medical device 12. The ablation generator 14 may be operable in one or more modes of operation, including for example: (i) bipolar energy delivery between at least two electrodes 24 or electrically-conductive portions of the medical device 12 within a patient's body, (ii) monopolar or unipolar energy delivery to one or more of the electrodes or electrically-conductive portions on the medical device 12within a patient's body and through either a second device within the body (not shown) or a patient return or ground electrode (not shown) spaced apart from the plurality of electrodes 24 of the medical device 12, such as on a patient's skin or on an auxiliary device positioned within the patient away from the medical device 12, for example, and (iii) a combination of the monopolar and bipolar modes.

The ablation generator 14 may provide electrical pulses to the medical device 12 to perform an electroporation procedure to cardiac tissue or other tissues within the body, for example, renal tissue, airway tissue, and organs or tissue within the cardiothoracic space. “Electroporation” utilizes high amplitude pulses to effectuate a physiological modification (i.e., permeabilization) of the cells to which the energy is applied. Such pulses may preferably be short (e.g., nanosecond, microsecond, or millisecond pulse width) in order to allow application of high voltage, high current (for example, 20 or more amps) without long duration of electrical current flow that results in significant tissue heating and muscle stimulation. In particular, the pulsed energy induces the formation of microscopic pores or openings in the cell membrane. Depending upon the characteristics of the electrical pulses, an electroporated cell can survive electroporation (i.e., “reversible electroporation”) or die (i.e., irreversible electroporation, “IEP”). Reversible electroporation may be used to transfer agents, including large molecules, into targeted cells for various purposes, including alteration of the action potentials of cardiac myocyctes.

The ablation generator 14 may be configured and programmed to deliver pulsed, high voltage electric fields appropriate for achieving desired pulsed, high voltage ablation (or pulsed field ablation). As a point of reference, the pulsed, high voltage, non-radiofrequency, ablation effects of the present disclosure are distinguishable from DC current ablation, as well as thermally induced ablation attendant with conventional RF techniques. For example, the pulse trains delivered by ablation generator 14 are delivered at a pulse repetition frequency less than 3 kHz, and in an example configuration, 1 kHz, which is a lower frequency than radiofrequency treatments. The pulsed-field energy in accordance with the present disclosure is sufficient to induce cell death for purposes of completely blocking an aberrant conductive pathway along or through cardiac tissue, destroying the ability of the so-ablated cardiac tissue to propagate or conduct cardiac depolarization waveforms and associated electrical signals.

The plurality of electrodes 24 may also perform diagnostic functions such as collection of intracardiac electrograms (EGM) as well as performing selective pacing of intracardiac sites for diagnostic purposes. In one configuration, the measured ECG signals, are transferred from the catheter electrode energy distribution system 13 to an EP recording system input box (not shown) which is included with ablation generator 14. The plurality of electrodes 24 may also monitor the proximity to target tissues and quality of contact with such tissues using impedance-based measurements with connections to the catheter electrode energy distribution system 13. The catheter electrode energy distribution system 13 may include high speed relays to disconnect/reconnected specific electrode 24 from the ablation generator 14 during therapies. Immediately following the pulsed energy deliveries, the relays reconnect the electrodes 24 so they may be used for diagnostic purposes.

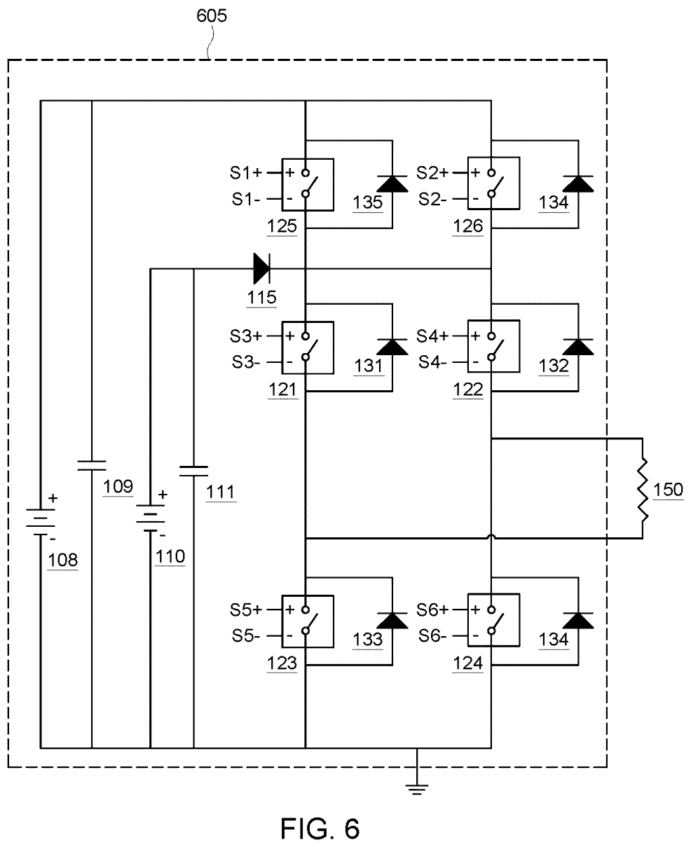

As shown in FIGS. 1A and 1B, ablation generator 14 can include a bipolar high voltage bipolar pulsing power supply 105. Alternatively, ablation generator 14 can include a power supply 605 or 1005 as depicted in FIGS. 6, 10, and 11. A high voltage bipolar pulsing power supply used in system 10 can produce high voltage bipolar pulses that include a positive high voltage pulse greater than about 100 V, 200 V, 500 V, 1 kV, 2 kV, 5 kV, 10 kV, etc. followed by a negative high voltage pulse less than about −100 V, −200 V, −500 V, −1 kV, −2 kV, −5 kV, 10 kV etc. with a positive to negative dwell between the positive high voltage pulse and the negative high voltage pulse. The high voltage bipolar pulsing power supply can reproduce these high voltage pulses with a high pulse repetition frequency greater than about 10 kHz.

FIG. 1A is an example illustration of a high voltage bipolar pulsing power supply 105 driving a load 150.

The high voltage bipolar pulsing power supply 105 may include a first DC source 110 and an energy storage capacitor 111. The first DC source 110, for example, may include a high voltage bipolar pulsing power supply that charges the energy storage capacitor 111. The energy storage capacitor 111, for example, may include a capacitor having a capacitance of about 80 nF to about 250 nF or about 2 □F to 100 □F.

The high voltage bipolar pulsing power supply 105, for example, may include the first switch circuit 121, the second switch circuit 122, the third switch circuit 123, and the fourth switch circuit 124. Each of the switch circuits 121, 122, 123, or 124, for example, may include a plurality of switches in series or in parallel such as, for example, four switches, eight switches, twelve switches, etc. arranged in parallel.

The first switch circuit 121 may be coupled with the first DC source 110 and a first side of load 150. The third switch circuit 123 may be coupled with ground and the first side of load 150 and first switch circuit 121. The second switch circuit 122 may be coupled with the first DC source 110 and a second side of the load 150. The fourth switch circuit 124 may be coupled with ground, the second side of load 150, and the second switch circuit 122.

Each of the switch circuits 121, 122, 123, and 124, for example, may include one or more of any type of solid-state switch such as, for example, IGBTs, a MOSFETs, a SiC MOSFETs, SiC junction transistors, FETs, SiC switches, GaN switches, photoconductive switches, etc. Each of the switch circuits 121, 122, 123, and 124 may be switched at high frequencies and/or may produce high voltage pulses. These frequencies may, for example, include frequencies of about 1 kHz, 5 kHz, 10 kHz, 25 kHz, 50 kHz, 100 kHz, etc.

Each switch of the switch circuits 121, 122, 123, and 124 may be coupled in parallel with a respective bridge diode, may have a stray capacitance, and/or may have stray inductance. The stray inductances of each of the switch circuits 121, 122, 123, and 124 may be substantially equal. The stray inductances of each of the switch circuits 121, 122, 123, and 124, for example, may be less than about 5 nH, 10 nH, 50 nH, 100 nH, 150 nH, etc. The stray capacitance of each of the switch circuits 121, 122, 123, and 124, for example, may be low such as, for example, less than about 400 nF, 200 nF, 100 nF, 50 nF, 25 nF, 10 nF, etc. If each switch of the switch circuits 121, 122, 123, and 124 may include multiple individual switches, then the combination of the multiple individual switches may have a capacitance of less than about 150 nF, 100 nF, 50 nF, 25 nF 10 nF, 5 nF, etc.

The combination of a switch (e.g., one of the switch circuits 121, 122, 123, or 124), a respective diode (e.g., one of diodes 131, 132, 133, and 134), and related circuitry may have a stray inductance of less than about 5 nH, 10 nH, 50 nH, 100 nH, 150 nH, etc. The high voltage bipolar pulsing power supply 105 may include low stray inductance throughout the circuit such as, for example, an inductance less than about 5 nH, 10 nH, 50 nH, 100 nH, 150 nH, 200 nH, etc.

The load 150 may comprise any type of load. For example, the load 150 may have an output resistance less than about 250 ohms, 100 ohms, 50 ohms, 25 ohms, 10 ohms, 5 ohms, 2 ohms, 1 ohm, etc. The load 150 may be part of an electrode for ablation and/or an electrode for electroporation, such as electrodes 24 shown in FIG. 1A. The load 150 may include a transformer that may be used to increase the power produced by the high voltage bipolar pulsing power supply 105.

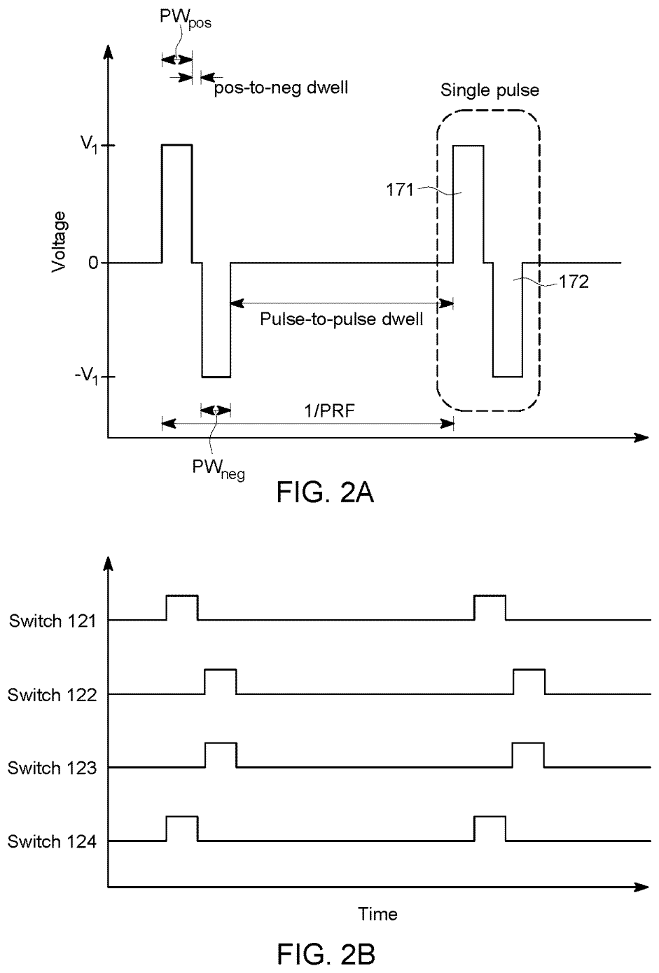

FIG. 2A shows an output waveform at the load 150 from the high voltage bipolar pulsing power supply 105. FIG. 2B shows the open and close switch logic of the switch circuits 121, 122, 123, and 124 to produce the waveforms shown in FIG. 2A. This output waveform comprises a positive pulse 171 and a negative pulse 172. When the first switch circuit 121 and the fourth switch circuit 124 are closed and the second switch circuit 122 and the third switch circuit 123 are open the positive pulse 171 is formed. When the second switch circuit 122 and the third switch circuit 123 are closed and the first switch circuit 121 and the fourth switch circuit 124 are open the negative pulse 172 is formed.

Each positive pulse 171 in FIG. 2A has a voltage of V1 and each negative pulse 172 in FIG. 2A has a negative voltage of −V1. The voltage V1 is the voltage from the energy storage capacitor 111 and/or the first DC source 110, V1. The time between the positive pulse 171 and the 172 is the dwell. The time between each consecutive positive pulse 171 is the inverse of the pulse repetition frequency (1/PRF). The time between the end of the first negative pulse 172 and the start of the first positive pulse is the pulse-to-pulse dwell. The pulse width of the positive pulse is the PWpos and the pulse width of the negative pulse is the PWneg.

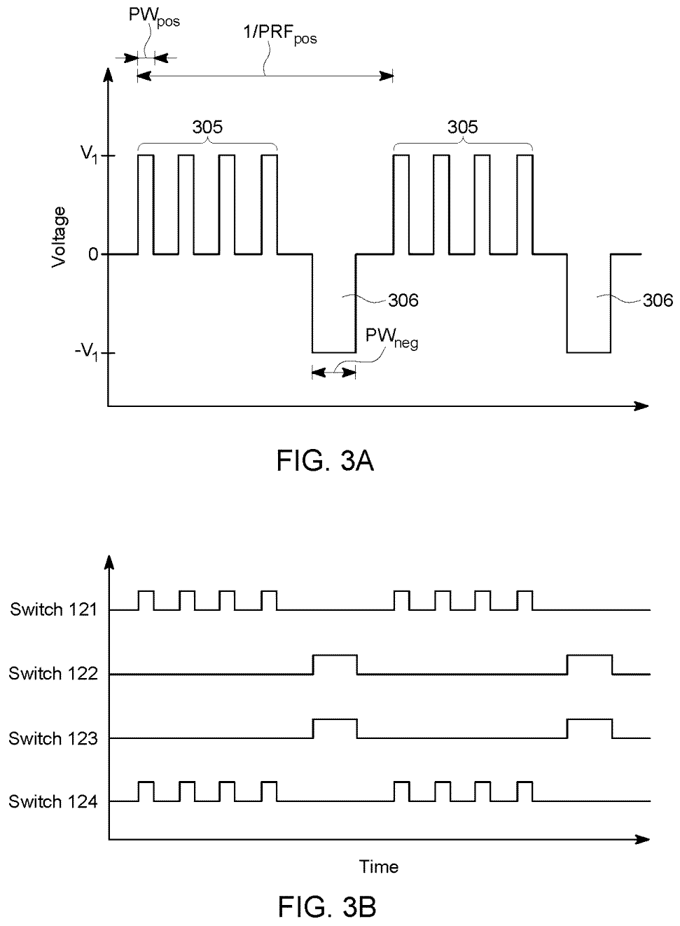

FIG. 3A shows an output waveform at the load 150 from the high voltage bipolar pulsing power supply 105 with a plurality of positive pulses 305 followed by a negative pulse 306. FIG. 3B shows the open and close switch logic of the switch circuits 121, 122, 123, and 124 to produce the waveforms shown in FIG. 3A. This output waveform comprises a plurality of positive pulses 305 and a longer negative pulse 306. When the first switch circuit 121 and the fourth switch circuit 124 are closed and the second switch circuit 122 and the third switch circuit 123 are open the each one of the plurality of positive pulses 305 are formed. When the second switch circuit 122 and the third switch circuit 123 are closed and the first switch circuit 121 and the fourth switch circuit 124 are open the negative pulse 306 is formed.

Each positive pulse of the plurality of positive pulses 305 in FIG. 3A has a voltage of V1 and each negative pulse 306 in FIG. 3A has a negative voltage of −V1. The voltage V1 is the voltage from the energy storage capacitor 111 and/or the first DC source 110, V1. Each pulse of the plurality of pulses 305 may have a pulse width of PWpos, and the pulse width of the negative pulse is the PWneg. The time between the first pulse of the plurality of positive pulses 305 and the next first pulse of the plurality of pulses 305 is the pulse repetition frequency (1/PRF).

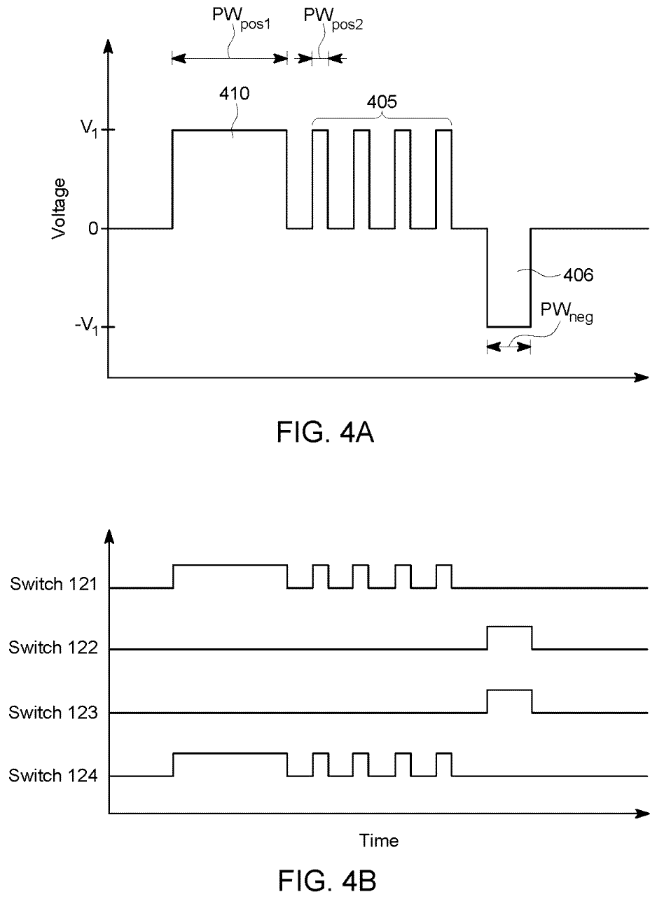

FIG. 4A shows an output waveform at the load 150 from the high voltage bipolar pulsing power supply 105 with a positive first longer pulse 410, a plurality of positive pulses 405 followed by a negative pulse 406. FIG. 3B shows the open and close switch logic of the switch circuits 121, 122, 123, and 124 to produce the waveforms shown in FIG. 4A. When the first switch circuit 121 and the fourth switch circuit 124 are closed and the second switch circuit 122 and the third switch circuit 123 are open the each one of the first positive pulse 410 and the plurality of positive pulses 405 are formed. When the second switch circuit 122 and the third switch circuit 123 are closed and the first switch circuit 121 and the fourth switch circuit 124 are open the negative pulse 406 is formed.

Each positive pulse of the plurality of positive pulses 405 and the long pulse 410 in FIG. 4A has a voltage of V1 and each negative pulse 406 in FIG. 4A has a negative voltage of −V1. The voltage V1 is the voltage from the energy storage capacitor 111 and/or the first DC source 110, V1. Each pulse of the plurality of pulses 405 may have a pulse width of PWpos2, the long positive pulse 410 may have a pulse width of PWpos1, and the pulse width of the negative pulse is the PWneg. The pulse width PWpos1 of the long pulse may be longer than the pulse width PWpos2 of each of the plurality of positive pulses 405 such as, for example, substantially more than two, three, four, five, ten, twenty, fifty, one hundred, five hundred, etc. times as long,

The time between the first pulse of the plurality of positive pulses 305 and the next first pulse of the plurality of pulses 305 is the pulse repetition frequency (1/PRF).

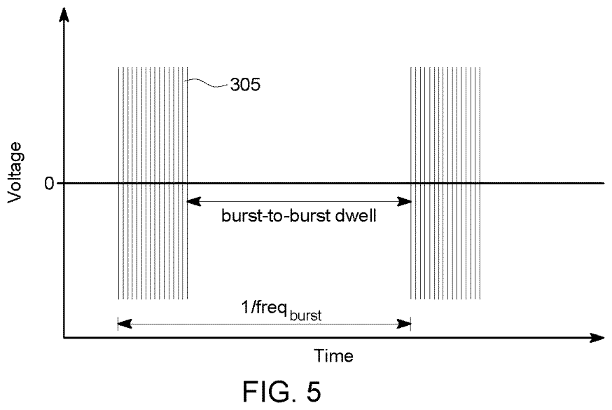

As shown in FIG. 5, the high voltage bipolar pulsing power supply 105 can produce burst pulses 305 that includes a plurality of bipolar pulses. The time between consecutive bursts is the burst-to-burst dwell and the time between the start of a first burst and the start of a second burst is the inverse of burst frequency (1/freqburst).

A controller (e.g., computational system 1300) may be coupled with each switch (e.g., the first switch circuit 121, the second switch circuit 122, the third switch circuit 123, and the fourth switch circuit 124) may control the opening and closing of these switch circuits. The controller may control the switch circuits to produce the waveforms shown in FIG. 2A by opening closing the switch circuits as shown in FIG. 2B. The controller may control the timing of the switch circuits to produce the waveforms shown in FIG. 3.

The controller can control the switch circuits to produce long pulse widths with a low pulse repetition frequency (PRF). For example, the controller can close the first switch circuit 121 and the fourth switch circuit 124 for a long duration (e.g., 5 ms, 2.5 ms, 1 ms, 500 ns, etc.), then open the first switch circuit 121 and the fourth switch circuit 124 and close the second switch circuit 122 and the third switch circuit 123 for a long duration (e.g., 5 ms, 2.5 ms, 1 ms, 500 ns, etc.), and then open the second switch circuit 122 and the third switch circuit 123. The controller can repeat this process after any period of time such as, for example, a pulse repetition frequency of 1 kHz, 10 kHz, 100 kHz, etc.

The controller can control the switch circuits to produce a plurality of short pulses (e.g., 250 ns, 500 ns, 1 ms, 5 ms, etc.) with a high pulse repetition frequency (e.g., 1 kHz, 5 kHz, 10 kHz, 25 kHz, etc.) within a burst and repeat the burst after a period of time (e.g., 250 ms, 500 ms, 1 s, 3 s, 5 s, etc.) such as, for example, as shown in FIG. 3. The controller can repeat these bursts, for example, hundreds or thousands of times.

FIG. 6 shows an example high voltage, multilevel, bipolar pulsing power supply 605 driving the load 150. The high voltage, multilevel, bipolar pulsing power supply 605 includes the high voltage bipolar pulsing power supply 105 and a fifth switch circuit 125 with a corresponding diode 135, a sixth switch circuit 126 with a corresponding diode 136, a second DC source 108, and a second energy storage capacitor 109. The fifth switch circuit 125 is coupled between the second DC source 108 and the first switch circuit 121. The sixth switch circuit 126 is coupled between the second DC source 108 and the second switch circuit 122. A diode may be included between the second DC source 108 and the fifth switch circuit 125 and between the second DC source 108 and the sixth switch circuit 126.

The second DC source 108 can produce a voltage greater than the first DC source 110.

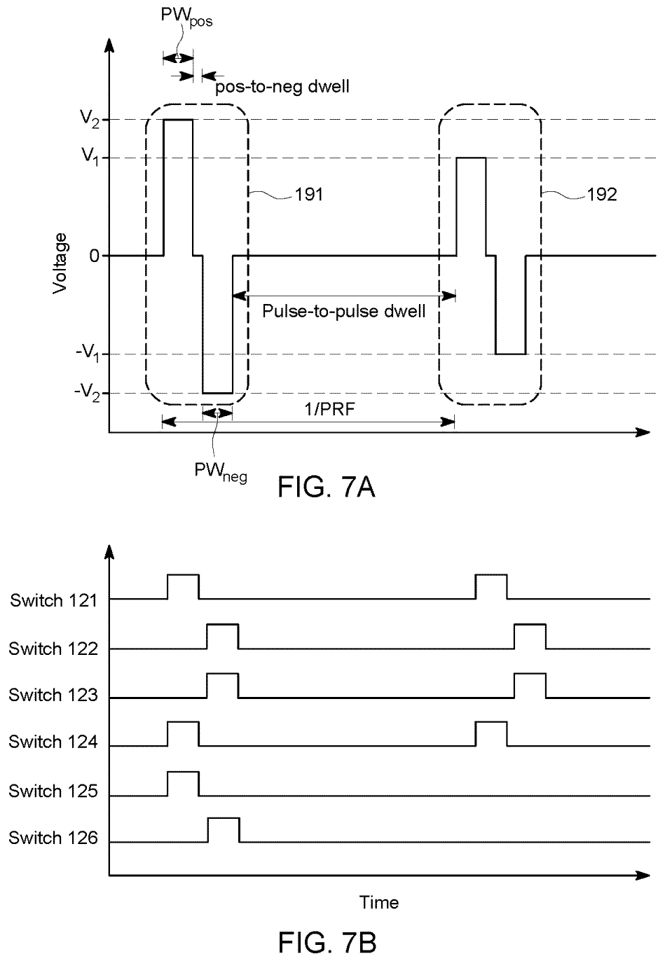

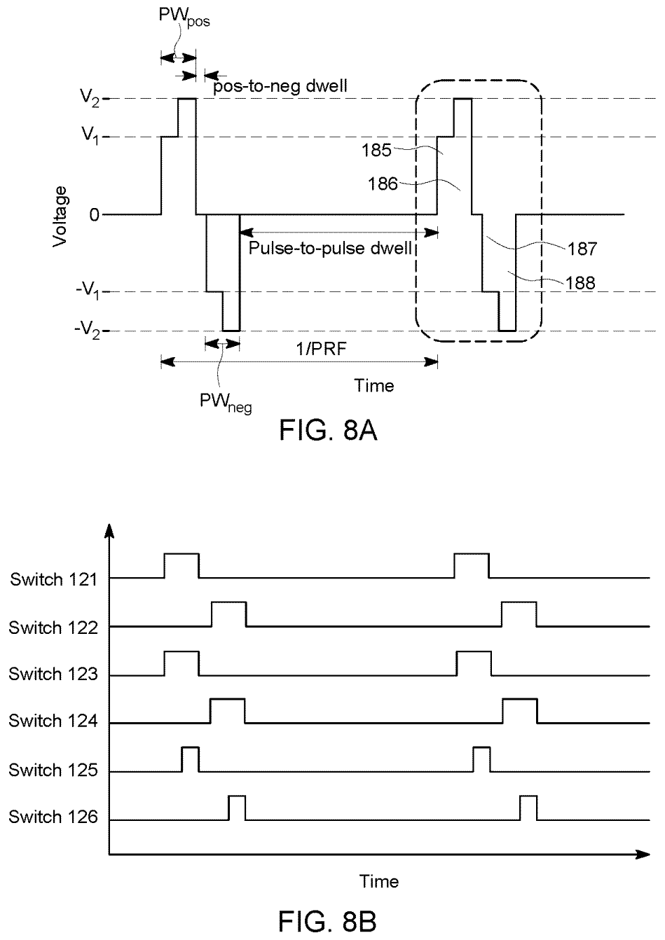

The diode 115 ensures charge flows from the energy storage capacitor 111, through the closed switch circuits, either the first switch circuit 121 and the fourth switch circuit 124 or the second switch circuit 122 and the third switch circuit 123 to the load 150. The high voltage, multilevel, bipolar pulsing power supply 605 can produce either 1) bipolar pulses with a high voltage as shown in FIG. 7A or 2) bipolar and multilevel pulses as shown in FIG. 8A. In FIG. 7A the first pulse 191 has a voltage of V1, which is the voltage of first DC source 110, and the second pulse 192 has a voltage V2, which is the voltage of the second DC source 108.

FIG. 7B shows the shows the open and close switch logic of the switch circuits 121, 122, 123, 124, 125, and 126, to produce the bipolar waveforms shown in FIG. 7A. The positive portion of the first pulse 191 is formed with a voltage V2, when the fifth switch circuit 125, the first switch circuit 121, and the fourth switch circuit 124 are closed and the sixth switch circuit 126, the second switch circuit 122 and the third switch circuit 123 are open. The negative portion of the first pulse 191 is formed with a voltage V2, when the sixth switch circuit 126, the second switch circuit 122, and the third switch circuit 123 are closed and the fifth switch circuit 125, the first switch circuit 121, and the fourth switch circuit 124 are open. The positive portion of the second pulse 192 is formed with a voltage V1, when the first switch circuit 121 and the fourth switch circuit 124 are closed and the sixth switch circuit 126, the second switch circuit 122, the fifth switch circuit 125, and the third switch circuit 123 are open. The negative portion of the second pulse 192 is formed with a voltage V2, when the second switch circuit 122 and the third switch circuit 123 are closed and the fifth switch circuit 125, the sixth switch circuit 126, the first switch circuit 121, and the fourth switch circuit 124 are open.

FIG. 8B shows the shows the open and close switch logic of the switch circuits 121, 122, 123, 124, 125, and 126 to produce the multilevel bipolar waveforms shown in FIG. 8A. When the first switch circuit 121 and the fourth switch circuit 124 are closed and the fifth switch circuit 125, the sixth switch circuit 126, the second switch circuit 122, and the third switch circuit 123 are open, first level positive pulse 185 is formed at voltage V1. When the switch, 125, the first switch circuit 121 and the fourth switch circuit 124 are closed and the sixth switch circuit 126, the second switch circuit 122, and the third switch circuit 123 are open, the second level positive pulse 186 is formed at voltage V2. The combination of the first level positive pulse 185 and the second level positive pulse 186 forms a multilevel positive pulse. When the second switch circuit 122 and the third switch circuit 123 are closed and the fifth switch circuit 125, the sixth switch circuit 126, the first switch circuit 121, and the fourth switch circuit 124 are open, the first level negative pulse 187 is formed at voltage −V1. When the switch, 126, the second switch circuit 122, and the third switch circuit 123 are closed and the fifth switch circuit 125, the first switch circuit 121, and the fourth switch circuit 124 are open, second level negative pulse 188 is formed at voltage −V2. The combination of the first level negative pulse 187 and the second level negative pulse 188 forms a multilevel negative pulse. The V2 is the voltage of the second DC source 108.

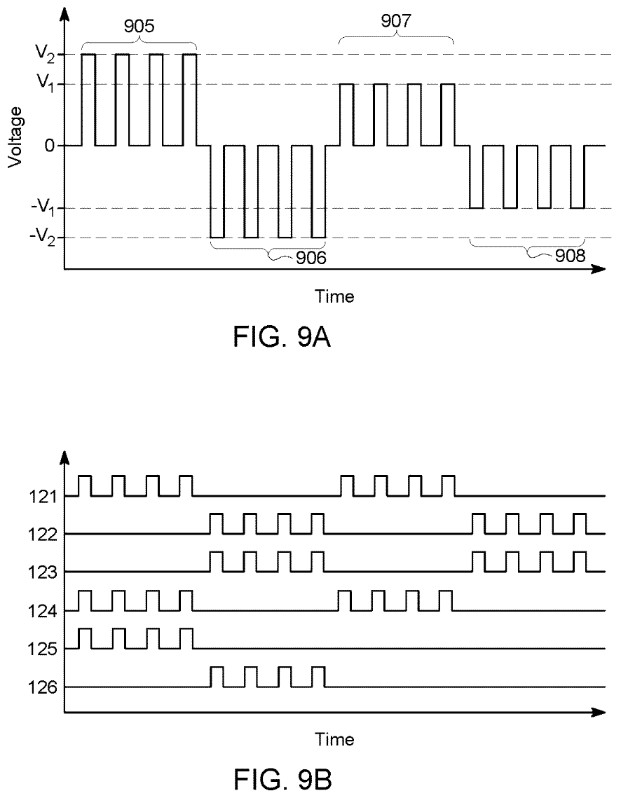

FIG. 9B shows the shows the open and close switch logic of the switch circuits 121, 122, 123, 124, 125, and 126 to produce the multilevel bipolar waveforms shown in FIG. 9A. FIG. 9A shows a first burst of pulses 905 having a voltage V2, a second burst of pulses 906 having a negative voltage V2, a third burst of pulses 907 having a voltage V1, and a fourth burst of pulses 908 having a negative voltage V1. The first burst of pulses 905 may include any number of pulses; the second burst of pulses 906 may include any number of pulses; the third burst of pulses 907 may include any number of pulses; and/or the fourth burst of pulses 908 may include any number of pulses. The bursts of pulses may occur in any order or sequence. The first burst of pulses 905, the second plurality of pulses 906, the third plurality of pulses 907, and/or the fourth plurality of pulses 908 may have any pulse repetition frequency and/or each pulse of the plurality of pulses may have any pulse widths.

The first burst of pulses 905 with a voltage V2 may be created by closing the first switch circuit 121, the fourth switch circuit 124, and the fifth switch circuit 125; and opening the second switch circuit 122, the third switch circuit 123, and the sixth switch circuit 126. The second burst of pulses 906 with a negative voltage V2 may be created by closing the second switch circuit 122, the third switch circuit 123, and the sixth switch circuit 126; and opening the first switch circuit 121, the fourth switch circuit 124, and the fifth switch circuit 125. The third burst of pulses 907 with a voltage V1 may be created by closing the first switch circuit 121 and the fourth switch circuit 124; and opening the second switch circuit 122, the third switch circuit 123, the fifth switch 125, and the sixth switch 126. The fourth burst of pulses 908 with a negative voltage V1 may be created by closing the second switch circuit 122 and the third switch circuit 123; and opening the first switch circuit 121, the fourth switch circuit 124, the fifth switch 125, and the sixth switch 126.

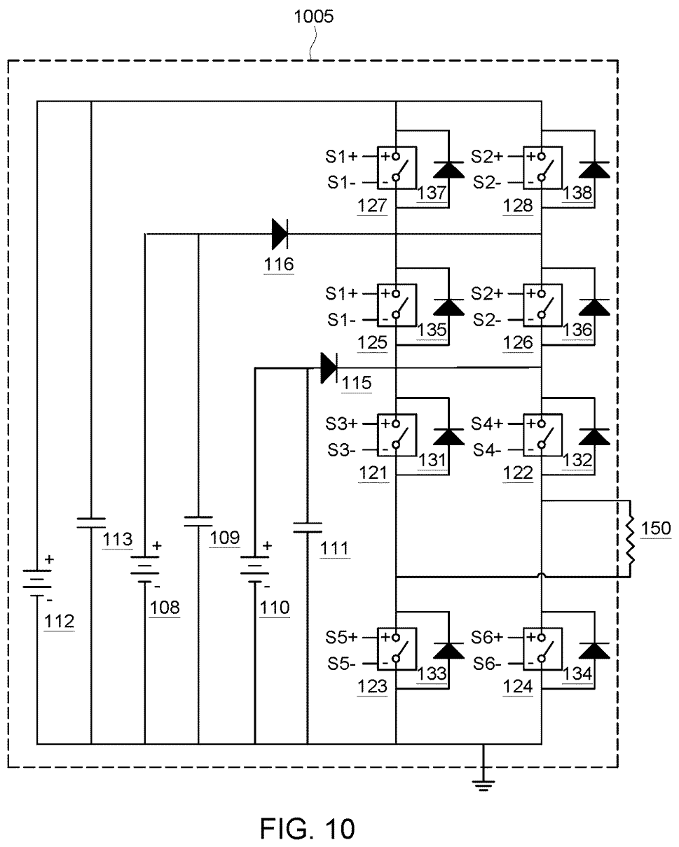

The bipolar pulsing power supply 605 may include additional switch circuit to produce additional multilevel pulses. FIG. 10 shows an example high voltage, multilevel, bipolar pulsing power supply 1005 with a seventh switch circuit 127 and an eighth switch circuit 128 coupled with a third DC source 112 and a third energy storage capacitor 113. The seventh switch circuit 127 may include a corresponding diode 137 and the eighth switch circuit 128 may include a corresponding diode 138. An additional diode 116 may also be included between the second DC source 108 and the second energy storage capacitor 109 and both the fifth switch circuit 125 and the sixth switch circuit 126. The third DC source 112 may have a voltage greater than the first DC source 110 and/or the second DC source 108. The high voltage bipolar pulsing power supply 1005 may produce multilevel pulses with three levels of voltage.

Additional DC sources and switch circuits may be added to create additional multilevel pulses of any number of voltage levels.

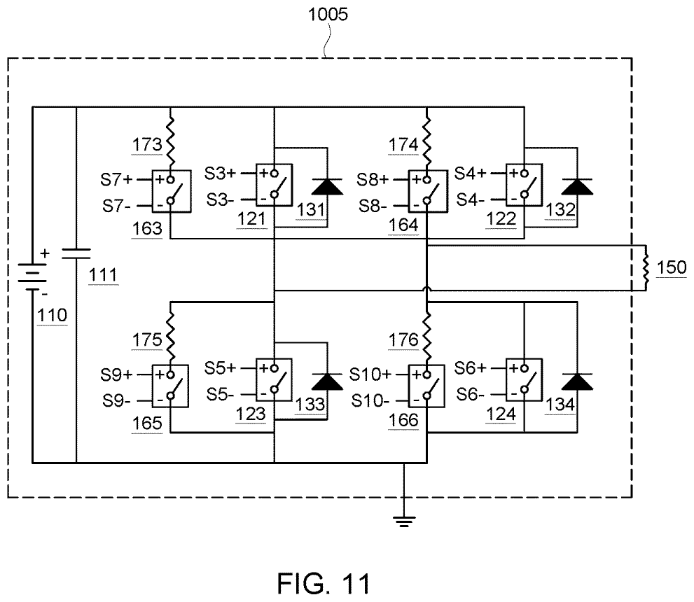

FIG. 11 shows an example high voltage bipolar pulsing power supply 1005 driving the load 150. In this example, the high voltage bipolar pulsing power supply 105 includes four tail sweeper switches (e.g., switches 163, 164, 165, 166) and corresponding tail sweeper resistors (e.g., resistors 173, 174, 175, and 176). Alternatively, the tail sweeper resistors can be replaced with inductors or capacitors.

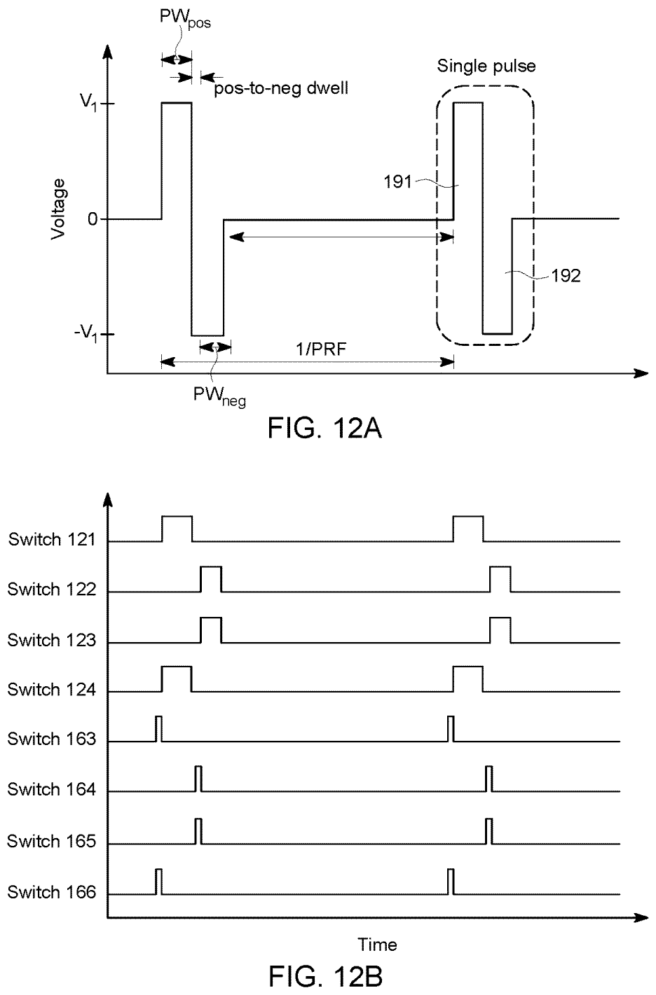

The first tail sweeper switch 163 and the first tail sweeper resistor 173 are coupled across the first switch circuit 121, the second tail sweeper switch 164 and the second tail sweeper resistor 174 are coupled across the second switch circuit 122, the third tail sweeper switch 165 and the third tail sweeper resistor 175 are coupled across the third switch circuit 123, and the fourth tail sweeper switch 166 and the fourth tail sweeper resistor 176 are coupled across the fourth switch circuit 124. Each tail sweeper switch can be closed prior to the corresponding switch circuit to dissipate any tail current in the circuit into the tail sweeper resistor as shown in FIG. 12B.

FIG. 12A shows bipolar pulses produced with the high voltage bipolar pulsing power supply 1005. FIG. 12B shows the shows the open and close switch logic of the switch circuits 121, 122, 123, 124, 125, and 126 and/or the tail sweeper switches 163, 164, 165, and 166 to produce the bipolar waveforms shown in FIG. 12A. For example, the tail sweeper switch 163 and the tail sweeper switch 166 are closed prior to closing the first switch circuit 121 and the fourth switch circuit 124. And the tail sweeper switch 164 and the tail sweeper switch 165 are closed prior to closing the second switch circuit 122 and the third switch circuit 123. By closing the tail sweeper switch 164 and the tail sweeper switch 165 prior to closing the second switch circuit 122 and the third switch circuit 123, the dwell between the positive pulse 191 and the negative pulse 192 can be substantially eliminated or completely eliminated.

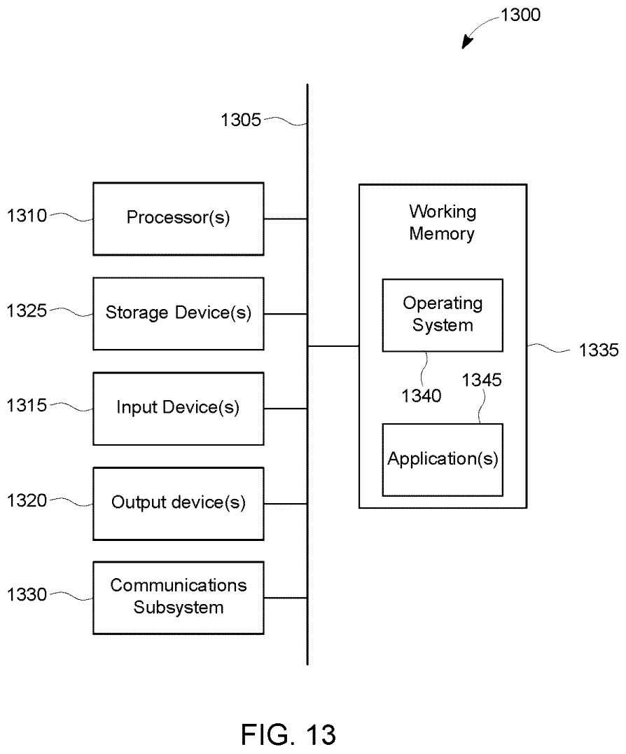

The computational system 1300, shown in FIG. 13 can be used to perform any of the examples disclosed in this document. For example, computational system 1300 can be used to control the switching of the various switch circuits described in this document. As another example, computational system 1300 can perform any calculation, identification and/or determination described here. The computational system 1300 may include hardware elements that can be electrically coupled via a bus 1305 (or may otherwise be in communication, as appropriate). The hardware elements can include one or more processors 1310, including without limitation one or more general-purpose processors and/or one or more special-purpose processors (such as digital signal processing chips, graphics acceleration chips, and/or the like); one or more input devices 1315, which can include without limitation a mouse, a keyboard and/or the like; and one or more output devices 1320, which can include without limitation a display device, a printer and/or the like.

The computational system 1300 may further include (and/or be in communication with) one or more storage devices 1325, which can include, without limitation, local and/or network accessible storage and/or can include, without limitation, a disk drive, a drive array, an optical storage device, a solid-state storage device, such as a random access memory (“RAM”) and/or a read-only memory (“ROM”), which can be programmable, flash-updateable and/or the like. The computational system 1300 might also include a communications subsystem 1330, which can include without limitation a modem, a network card (wireless or wired), an infrared communication device, a wireless communication device and/or chipset (such as a Bluetooth device, an 802.6 device, a Wi-Fi device, a WiMax device, cellular communication facilities, etc.), and/or the like. The communications subsystem 1330 may permit data to be exchanged with a network (such as the network described below, to name one example), and/or any other devices described in this document. In examples some examples, the computational system 1300 will further include a working memory 1335, which can include a RAM or ROM device, as described above.

The computational system 1300 also can include software elements, shown as being currently located within the working memory 1335, including an operating system 1340 and/or other code, such as one or more application programs 1345, which may include computer programs of the invention, and/or may be designed to implement methods of the invention and/or configure systems of the invention, as described herein. For example, one or more procedures described with respect to the method(s) discussed above might be implemented as code and/or instructions executable by a computer (and/or a processor within a computer). A set of these instructions and/or codes might be stored on a computer-readable storage medium, such as the storage device(s) 1325 described above.

In some cases, the storage medium might be incorporated within the computational system 1300 or in communication with the computational system 1300. In other examples, the storage medium might be separate from a computational system 1300 (e.g., a removable medium, such as a compact disc, etc.), and/or provided in an installation package, such that the storage medium can be used to program a general-purpose computer with the instructions/code stored thereon. These instructions might take the form of executable code, which is executable by the computational system 1300 and/or might take the form of source and/or installable code, which, upon compilation and/or installation on the computational system 1300 (e.g., using any of a variety of generally available compilers, installation programs, compression/decompression utilities, etc.) then takes the form of executable code.

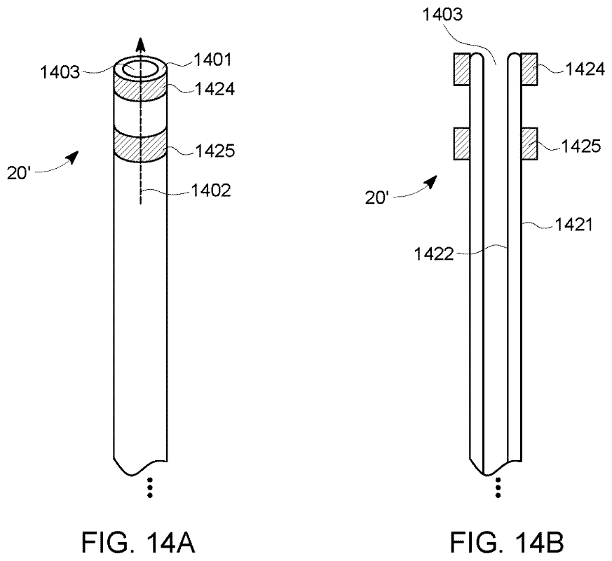

FIGS. 14A and 14B show a schematic of an alternative ablation catheter 20′ that may be used in system 10 of FIG. 1A. FIG. 14A shows a side view of an ablation catheter and FIG. 14B shows a cross-section view along a plane through the catheter's longitudinal axis 1402. Catheter 20′ is shown as having a central lumen 1403 inside a tubular element, and two electrodes on the outer surface 1421 of the tube: electrode 1424 is at or near the tip of the catheter at its distal end 1401, and electrode 1425 is located down the tube of the catheter away from the tip electrode. In FIGS. 14A and 14B, the electrodes are not attached to the inner surface 1422. When a voltage difference is applied between the two electrodes, they form a dipole. Tissue may be ablated by electroporation where the electric field directly induces cell damage.

Some ablation catheters have more than two electrodes on the outer surface 1421 of the catheter 20′. For cardiac applications for example, specialized multielectrode catheters can deliver electroporation to the ostium of pulmonary veins within the left atrium. Most of these devices are designed to perform anatomic ablation of the pulmonary veins to treat a common arrythmia called atrial fibrillation.

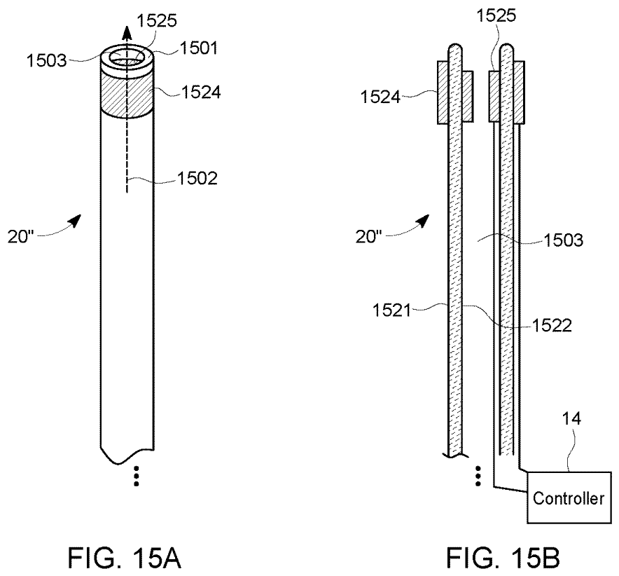

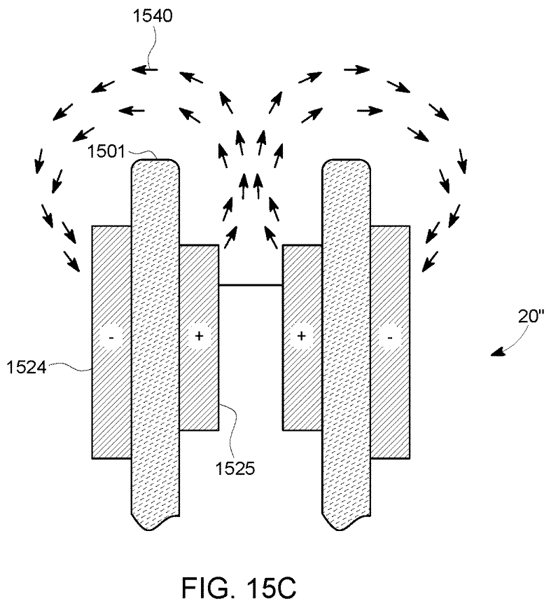

FIGS. 15A and 15B 2B depict an example of another alternative catheter 20″, which can be used in system 10 of FIG. 1A. Catheter 20″ has an outer electrode 1524 attached to the outer surface 1521 of the tubular catheter body, and an inner electrode 1525 attached to the inner surface 1522 (facing the lumen 1503) of the tubular catheter body. Both electrodes 1524 and 1525 are offset along the longitudinal axis 1502 from the distal end 1501 of the catheter; there is no electrode at the catheter tip. A distance between the outer electrode 1524 and the distal end 1501 may be at least 0.01 millimeters.

In applications, the distal end of the catheters 20, 20′, and 20″ may be placed at or near a tissue to be ablated. In the case of FIGS. 15A-15C, the outer electrode 1524 may be in contact with the tissue while inner electrode 1525 is not in direct contact with the tissue to be ablated. The electrodes may generate an electric field outside the tubular catheter body that induces ablation of nearby tissue via electroporation.

In some cases, lumen 1403 or 1503 of FIGS. 14A-15C of the catheter 20′ or 20″ may carry an irrigation fluid that is infused into the tissue; this fluid may be conductive. An illustrative fluid may be 9% normal saline, for example.

In some cases, inner electrode 1525 and outer electrode 1524 are separated by the distal portion of the catheter body, which may contain an electrically insulating material. In one or more examples the conductivity of this insulating material may be less than 0.1 micro-Siemens per centimeter, for example. In one or more examples this material may be a dielectric and it may have a high dielectric constant. An illustrative material that may be used in one or more examples may be aluminum nitride ceramic for example. (The portion of the catheter body below the electrodes (away from the distal end) may or may not be made of the same material as the portion of the body between the electrodes.) All or a portion of the catheter body may be flexible. The tubular catheter body may be of any desired length.

Electrodes 1524 and 1525 may be coupled to a generator/controller 14 that may set the voltage of each electrode, as shown in FIG. 15B. (The wires connecting the controller to the electrode are shown schematically as separated from the catheter body for ease of illustration; in applications these wires may be integrated into or attached to the catheter body, for example.) Generator/controller 14 may deliver voltage pulses to the electrodes 1524 and 1525. The pulses may be for example monophasic pulses with a duration between 10 ns and 10 ms, <50% duty cycle, amplitude between 1 kV-10 kV, pulse repetition between 1 and 10,000 pulses/second, inclusive. In particular, in one or more examples of the invention the voltage applied between at least one inner electrode and at least one outer electrode may be greater than 5000 volts. However, any electric potential pattern could be used with this electrode configuration including but not limited to multiple duration rectangular pulses, biphasic rectangular or trapezoidal waves, sinusoidal bipolar, sinusoidal offset, asymmetric rectangular, asymmetric rectilinear, and/or any combination of arbitrary waveform or pulse pattern combination.

FIG. 15C illustrates a similar bending effect on the shape of the electric field generated when a voltage difference is applied between the electrodes. The electric field lines 1540 bend around the distal end of the catheter. The dielectric in the catheter body amplifies the field strength as it bends around the tip.

Unless otherwise specified, the term “substantially” means within 5% or 10% of the value referred to or within manufacturing tolerances. Unless otherwise specified, the term “about” means within 5% or 10% of the value referred to or within manufacturing tolerances.

The conjunction “or” is inclusive.

The terms “first”, “second”, “third”, etc. are used to distinguish respective elements and are not used to denote a particular order of those elements unless otherwise specified or order is explicitly described or required.

Numerous specific details are set forth to provide a thorough understanding of the claimed subject matter. However, those skilled in the art will understand that the claimed subject matter may be practiced without these specific details. In other instances, methods, apparatuses or systems that would be known by one of ordinary skill have not been described in detail so as not to obscure claimed subject matter.

While the present subject matter has been described in detail with respect to specific examples thereof, it will be appreciated that those skilled in the art, upon attaining an understanding of the foregoing, may readily produce alterations to, variations of, and equivalents to such examples. Accordingly, present disclosure has been presented for purposes of example rather than limitation, and does not preclude inclusion of such modifications, variations and/or additions to the present subject matter as would be readily apparent to one of ordinary skill in the art.

That which is claimed:

1. An ablation system comprising a power supply, the power supply being adapted to produce high voltage bipolar pulses with a positive high voltage pulse greater than about 200 V followed by a negative high voltage pulse less than about −200 V.

2. The ablation system according to claim 1, wherein the power supply is adapted to produce high voltage bipolar pulses with a positive high voltage pulse greater than about 500 V followed by a negative high voltage pulse less than about −500 V.

3. The ablation system according to claim 1, wherein the output high voltage pulses with a pulse repetition frequency greater than about 10 kHz.

4. The ablation system according to claim 1, wherein the power supply comprises:
a DC source;
an energy storage capacitor coupled with the DC source;
a first high voltage switch electrically coupled with the DC source and the energy storage capacitor;
a first diode arranged across the first high voltage switch;
a second high voltage switch electrically coupled with the DC source and the energy storage capacitor;
a second diode arranged across the second high voltage switch;
a third high voltage switch arranged in series between the first high voltage switch and ground;
a third diode arranged across the third high voltage switch;
a fourth high voltage switch arranged in series between the second high voltage switch and ground;
a fourth diode arranged across the fourth high voltage switch; and
an output having a first lead electrically coupled between first high voltage switch and the third high voltage switch and the second lead electrically coupled between second high voltage switch and the fourth high voltage switch.

5. The ablation system according to claim 4, wherein the first high voltage switch comprises a first plurality of solid state switches arranged in parallel, the second high voltage switch comprises a second plurality of solid state switches arranged in parallel, the third high voltage switch comprises a third plurality of solid state switches arranged in parallel, and the fourth high voltage switch comprise a fourth plurality of solid state switches arranged in parallel.

6. The ablation system according to claim 4, wherein the first high voltage switch, the second high voltage switch, the third high voltage switch, and the fourth high voltage switch each comprise a switch selected from the group consisting of an IGBT, a MOSFET, a SiC MOSFET, a SiC junction transistor, a FET, a SiC switch, a GaN switch, and a photoconductive switch.

7. The ablation system according to claim 4, wherein the circuit comprising both the DC source and the energy storage capacitor has an inductance less than about 10 nH, and wherein the circuit comprising both the first high voltage bipolar pulsing power supply and the second high voltage switch has an inductance less than about 10 nH.

8. The ablation system according to claim 4, further comprising:
a first tail sweeper switch and a first tail sweeper resistor arranged in series across the first high voltage switch;
a second tail sweeper switch and a second tail sweeper resistor arranged in series across the first high voltage switch;
a third tail sweeper switch and a third tail sweeper resistor arranged in series across the first high voltage switch; and
a fourth tail sweeper switch and a fourth tail sweeper resistor arranged in series across the first high voltage switch.

9. A high voltage, multilevel, bipolar pulsing power supply comprising:
a first DC source;
a first energy storage capacitor coupled with the first DC source;
a first diode having an anode and a cathode, the anode electrically coupled with the first DC source and the first energy storage capacitor;
a first high voltage switch electrically coupled with the cathode of the first diode;
a first diode arranged across the first high voltage switch;
a second high voltage switch electrically coupled with the cathode of the first diode;
a second diode arranged across the second high voltage switch;
a third high voltage switch arranged in series between the first high voltage switch and ground;
a third diode arranged across the third high voltage switch;
a fourth high voltage switch arranged in series between the second high voltage switch and ground;
a fourth diode arranged across the fourth high voltage switch;
a second DC source;
a second energy storage capacitor coupled with the second DC source;
a fifth high voltage switch electrically coupled with the second DC source and the second energy storage capacitor;
a fifth diode arranged across the fifth high voltage switch;
a sixth high voltage switch electrically coupled with the cathode of the second DC source and the second energy storage capacitor;
a sixth diode arranged across the sixth high voltage switch; and
an output having a first lead electrically coupled between first high voltage switch and the third high voltage switch and the second lead electrically coupled between second high voltage switch and the fourth high voltage switch.

10. The ablation system according to claim 1, further comprising an electrode for electroporation.

11. The ablation system according to claim 10, further comprising a tissue ablation catheter, the tissues ablation catheter comprising the electrode for electroporation, wherein the power supply is adapted to supply high voltage bipolar pulses to the electrode for electroporation.

12. The ablation system according to claim 11, wherein the tissue ablation catheter comprises a plurality of electrodes for electroporation including at least one or more first electrodes and one or more second electrodes.

13. The ablation system according to claim 12, wherein the one or more first electrodes are insulated from the one or more second electrodes with a tubular insulating element, the one or more first electrodes being positioned outside of the tubular insulating element and the one or more second electrodes being positioned inside the tubular insulating element.

14. The ablation system according to claim 13, further comprising a controller configured to set voltages for pulses of the one or more first electrodes and voltages for pulses of the one or more second electrode to generate an electric field outside said tubular insulating element that induces ablation of tissue to be ablated by electroporation.

15. The ablation system according to claim 13, wherein the controller is further configured to modify voltages to the first electrode and the second electrode over time to change a direction of the electric field.

16. An ablation device comprising a power supply, the power supply being adapted to produce high voltage bipolar pulses with a positive high voltage pulse greater than about 200 V followed by a negative high voltage pulse less than about −200 V.

17. The ablation device according to claim 16, wherein the power supply is adapted to produce high voltage bipolar pulses with a positive high voltage pulse greater than about 500 V followed by a negative high voltage pulse less than about −500 V, wherein the output high voltage pulses with a pulse repetition frequency greater than about 10 kHz.

18. The ablation device according to claim 16, wherein the power supply comprises:
a DC source;
an energy storage capacitor coupled with the DC source;
a first high voltage switch electrically coupled with the DC source and the energy storage capacitor;
a first diode arranged across the first high voltage switch;
a second high voltage switch electrically coupled with the DC source and the energy storage capacitor;
a second diode arranged across the second high voltage switch;
a third high voltage switch arranged in series between the first high voltage switch and ground;
a third diode arranged across the third high voltage switch;
a fourth high voltage switch arranged in series between the second high voltage switch and ground;
a fourth diode arranged across the fourth high voltage switch; and
an output having a first lead electrically coupled between first high voltage switch and the third high voltage switch and the second lead electrically coupled between second high voltage switch and the fourth high voltage switch.

19. A method of ablation, the method comprising producing a high voltage bipolar pulse with a positive high voltage pulse greater than about 200 V followed by a negative high voltage pulse less than about −200 V and applying it to an electrode for electroporation.

20. The method according to claim 19, wherein cardiac tissue is ablated.
